(19) United States
(12) Patent Application Publication
(10) Pub. No.: US 2010/0301449 A1
(43) Pub. Date: Dec. 2, 2010

(54) METHODS AND APPARATUS FOR FORMING LINE AND PILLAR STRUCTURES FOR THREE DIMENSIONAL MEMORY ARRAYS USING A DOUBLE SUBTRACTIVE PROCESS AND IMPRINT LITHOGRAPHY

(75) Inventors: Roy E. Scheuerlein, Cupertino, CA (US); Yung-Tin Chen, Santa Clara, CA (US)

Correspondence Address: DUGAN & DUGAN, PC, 245 Saw Mill River Road, Suite 309, Hawthorne, NY, 10532, US

(73) Assignee: SANDISK 3D LLC, Milpitas, CA (US)

(21) Appl. No.: 12/856,392

(22) Filed: Aug. 13, 2010

Related U.S. Application Data
(63) Continuation-in-part of application No. 11/967,638, filed on Dec. 31, 2007.

(51) Int. Cl. H01L 27/02; H01L 21/02; B29C 59/02

(52) U.S. Cl. 257/528; 438/381; 425/385; 257/E21.003; 257/E27.009

(57) ABSTRACT

The present invention provides systems, apparatus, and methods for forming three dimensional memory arrays using a multi-depth imprint lithography mask and a double subtractive process. An imprint lithography mask for manufacturing a memory layer in a three dimensional memory is described. The mask includes a translucent material formed with features for making an imprint in a transfer material to be used in a double subtractive process, the mask having a plurality of imprint depths. At least one imprint depth corresponds to rails for forming memory lines and at least one depth corresponds to pillars for forming memory cells. Numerous other aspects are disclosed.

### CROSS REFERENCE TO RELATED APPLICATIONS

This application is a continuation-in-part of non-provisional U.S. patent application Ser. No. 11/967,638, entitled “Methods And Apparatus For Forming Memory Lines And Vias In Three Dimensional Memory Arrays Using Dual Damascene Process And Imprint Lithography,” filed Dec. 31, 2007, which is herein incorporated by reference in its entirety.

The present application is also related to the following patent applications, each of which is hereby incorporated by reference herein in its entirety for any purpose:

U.S. patent application Ser. No. 10/728,451, filed on Dec. 5, 2003, and entitled “High Density Contact to Relaxed Geometry Layers”;

U.S. patent application Ser. No. 11/751,567, filed on May 21, 2007, and entitled “Memory Array Incorporating Memory Cells Arranged in NAND Strings”;

U.S. patent application Ser. No. 10/335,078, filed on Dec. 31, 2002, and entitled “Programmable Memory Array Structure Incorporating Series-Connected Transistor Strings and Methods for Fabrication and Operation of Same;” and

U.S. Pat. No. 6,951,780, issued Oct. 4, 2005, and entitled “Selective Oxidation of Silicon in Diode, TFT, and Monolithic Three Dimensional Memory Arrays.”

### FIELD OF THE INVENTION

The present invention relates to semiconductor manufacturing techniques and more particularly to forming memory lines and pillars in three dimensional memory arrays using a double subtractive process and imprint lithography.

### BACKGROUND

The formation of pillars conventionally requires the use of relatively expensive leading edge etch tools. Further, each of the mask steps involved in forming pillars conventionally require the use of relatively expensive leading edge immersion lithography tools and techniques. Further, formation of pillars using immersion lithography when feature sizes reach 32 nm to 15 nm will become even more costly and may not even be possible. Thus, what is needed are pillar forming methods and apparatus that do not require the use of immersion lithography and that reduce the cost of manufacturing submicron three-dimensional memory arrays that use pillars.

### SUMMARY

According to aspects of the present invention, a method of forming a memory layer in a three-dimensional memory array is provided. The method includes forming a template having a plurality of depths, wherein at least one depth corresponds to a memory line and wherein at least one depth corresponds to a pillar; imprinting the template into a transfer material; curing the transfer material; and forming a memory layer using the imprinted and cured transfer material.

According to other aspects, the present invention provides a memory layer in a three-dimensional memory array. The memory layer includes a plurality of memory lines and pillars formed by a double subtractive process using an imprint lithography template having a plurality of depths, wherein at least one depth corresponds to the memory lines and wherein at least one depth corresponds to the pillars; and a plurality of memory cells formed, one in each of the pillars, and operatively coupled to the memory lines.

According to other aspects, the present invention provides an imprint lithography mask for manufacturing a memory layer in a three dimensional memory. The mask includes a translucent material formed with features for making an imprint in a transfer material to be used in a double subtractive process, the mask having a plurality of imprint depths. At least one imprint depth corresponds to trenches for forming memory lines and wherein at least one depth corresponds to holes for forming pillars.

According to other aspects, the present invention provides a three dimensional memory array that includes a plurality of horizontal memory layers formed on top of each other and electrically coupled to each other. The memory layers include a plurality of memory lines and pillars which are both formed concurrently using an imprint lithography mask.

Other features and aspects of the present invention will become more fully apparent from the following detailed description, the appended claims and the accompanying drawings.

### BRIEF DESCRIPTION OF THE DRAWINGS

FIG. 1 is a perspective view of a structural representation of interleaved word lines and bit lines of a simplified example three-dimensional memory array according to embodiments of the present invention.

FIG. 2 is a perspective view of an example imprint lithography mask suitable for forming the memory lines of the three-dimensional memory array of FIG. 1 according to embodiments of the present invention.

FIG. 3 is a perspective view of a second example imprint lithography mask suitable for forming memory lines and pillars of a three-dimensional memory array according to embodiments of the present invention.

FIGS. 4AX through 4EX and 4AY through 4EY depict a sequence of cross-sectional views (from a front (X) and a side (Y) perspective, respectively) of a substrate with various process layers, the sequence representing a first example method of forming a layer of memory lines and pillars in accordance with embodiments of the present invention.

FIG. 5 depicts a perspective view of an example three dimensional memory layer formed according to the process illustrated in FIGS. 4AX through 4EX and 4AY through 4EY.

FIGS. 6AX through 6EX and 6AY through 6EY depict a sequence of cross-sectional views (from a front (X) and a side (Y) perspective, respectively) of a substrate with various process layers, the sequence representing a second example method of forming a layer of memory lines and pillars in accordance with embodiments of the present invention.

FIGS. 6EX′ and 6EY′ in combination with FIGS. 6AX through 6DX and 6AY through 6DY depict a sequence of cross-sectional views (from a front (X) and a side (Y) perspective, respectively) of a substrate with various process layers, the sequence representing a third example method of forming a layer of memory lines and pillars in accordance with embodiments of the present invention.

FIGS. 7AX through 7EX and 7AY through 7EY depict a sequence of cross-sectional views (from a front (X) and a side (Y) perspective, respectively) of a substrate with various process layers, the sequence representing an example method of forming a layer of memory lines and conductive vias in accordance with embodiments of the present invention.

FIGS. 8X and 8Y are cross-sectional views of an alternative memory level structure for use in a three-dimensional memory array according to embodiments of the present invention.

### DETAILED DESCRIPTION

The present invention provides methods and apparatus for forming a three-dimensional memory array (e.g., a monolithic three-dimensional memory array with multiple levels on a single substrate and/or stacked levels of two-dimensional arrays formed on different substrates and subsequently bonded together) using a double depth imprint lithography mask (e.g., a 3D template) to concurrently form rails and pillars for memory lines and memory cells, respectively. More specifically, rails and pillars are formed using a double subtractive process where the first feature of the double subtractive process may be horizontal word or bit lines and the second feature may be one or more vertical pillar-shaped memory cells on the word or bit lines. The imprint lithography mask may include a series of trenches with holes disposed along the length of the trenches. The trenches are used to form the rails for the memory lines and the holes are used to form the pillars for the memory cells. The present invention thus reduces the number of masking steps required to build three-dimensional memory arrays and also reduces the use of expensive deep submicron optical lithography tools and double patterning techniques. In fact, the present invention reduces the number of exposures needed to form an array by a factor of four relative to conventional double patterning of pillars and memory lines.

Conventional double patterning defines half the memory lines in a first exposure step where the line width is approximately the desired feature size but the space between the lines is three times the feature size. Then the second half of the lines is defined in a second exposure step in the gap. The resulting memory lines are defined at a pitch of two features which is smaller than the pitch achievable by a single exposure step in the lithography tool set but at the cost of two exposures. Similarly, half the pillars can be defined by a first exposure and the second half can be defined by a second exposure. This results in pillars at the desired feature size and pitch. In total, to form the desired structure, four exposures are thus required by the prior art. In contrast, the present invention achieves the desired feature size and spacing with a single resist patterning step for a reduction of four to one. In other words, the present invention facilitates concurrent formation of pillars and rails made of conductive or semiconducting material.

Once the imprint template has been applied to resist material on a layer stack of process materials, the resist material is cured (e.g., via UV light transmitted though the translucent template) and a series of etching steps are used to transfer the complement of the template into the layer stack of process materials. In other words, a material layer of a semiconductor structure (e.g., a top layer of a layer stack of process materials) is temporarily etched into a first shape, which is the actual the shape of a second layer, and then the first layer is etched into its final shape. More specifically, etching is used to form a smaller shape (e.g., pillars) in a first material and a larger shape (e.g., rails) in second material. For example, the first material (e.g., polysilicon) is initially etched into rail shapes which define the rail shapes that will be transferred into the second material (e.g., tungsten (W)) in a second etch step. The first material is also etched into pillar shapes (e.g., pillars of polysilicon) in a third etch step. Note that the second and third etch steps may be one common etch step, or the third etch step may include the second etch step plus additional etching.

In an alternative embodiment of the invention, a hard mask material may be deposited on top of the layer stack of process materials before the resist material is deposited. In this embodiment, both the resist material and the hard mask material are used to transfer the dual topography of the template to the layer stack of process materials.

In yet another alternative embodiment of the invention, the methods of the present invention may be used to form memory lines and conductive vias that allow different memory layers to be coupled together. In such an embodiment, as with the memory lines and pillars, both the lines and vias are formed using an imprint lithography mask with at least two features of different depths. However, in this embodiment, the lines and vias are formed from the same conductive material (e.g., tungsten).

In a further embodiment, semiconductor material pillars and semiconductor material lines may be concurrently formed using the methods of the present invention. For example, the deposited layers may include a memory material layer on top of relatively thick semiconductor material. The semiconductor material layer stack under the memory material may include, for example, an N-I-P doped structure suitable for forming diodes. According to the present invention, the memory material is formed into pillar shapes and the semiconductor material is partially formed into pillar shapes and partially formed into the shape of lines. This structure results in a reduced aspect ratio of the semiconductor material etch. The resulting pillars have enhanced adhesion and/or resistance to toppling due to the reduced aspect ratio and the continuous material connection to the line shape. In some embodiments, a conductive rail may be formed below the semiconductor material in a separate lithography step. Further, the memory material may be one time programmable (OTP) or rewritable or any suitable memory material for forming a passive element cell including, for example, carbon nanotube material.

In some embodiments, a multi-level memory array according to the present invention includes memory cells formed on each of several memory planes or memory levels. Passive element memory cells or strings of such memory cells on more than one layer may be connected to global bit lines on a single layer. Such a global bit line layer may be disposed on a layer of a monolithic integrated circuit below all the memory levels for more convenient connection to support circuitry for the memory array, which may be disposed in the substrate below the array. In some embodiments, such a global bit line layer may reside in the midst of the memory levels, or above the array, and more than one global bit line layer may be used. Moreover, passive element memory cells or strings of such memory cells on more than one layer may also be connected to shared bias nodes on a single layer, which may be disposed above all the memory levels. In some embodiments, the shared bias nodes may reside in the midst of the memory levels, or below the array. The shared bias nodes may likewise be disposed on more than one layer.

Because some memory arrangements (e.g., a non-mirrored arrangement) may use a global bit line for each adjacent passive element memory cell or string of memory cells, the pitch of global bit lines may be tighter than for other arrangements in which adjacent strings of memory cells share the same global bit line. To alleviate global bit line pitch problems, in certain embodiments global bit lines may be routed on two or more wiring layers. For example, even-numbered cells or strings of memory cells may be associated with global bit lines disposed on one global bit line layer, while odd-numbered cells or strings of memory cells may be associated with global bit lines disposed on another global bit line layer. Thus, it may be desirable to have vias that reach down to different levels of bit lines between word lines layers. It may also be desirable to stagger vias to help match the pitch of cells or strings of memory cells, and the required global bit line pitch relaxed to twice the pitch of individual cells or strings of memory cells.

Vertical vias that contact more than two vertically adjacent layers may also be used, particularly for three-dimensional arrays having more than one plane of memory cells. Such a vertical connection may be conveniently termed a “zia” to imply a via-type structure connecting more than one layer in the z-direction. Preferred zia structures and related methods for their formation are described in U.S. Pat. No. 6,534,403 to Cleeves, issued Mar. 18, 2003, the disclosure of which is hereby incorporated by reference in its entirety. Additional details of exemplary zias are described in previously incorporated U.S. patent application Ser. No. 10/335,078.

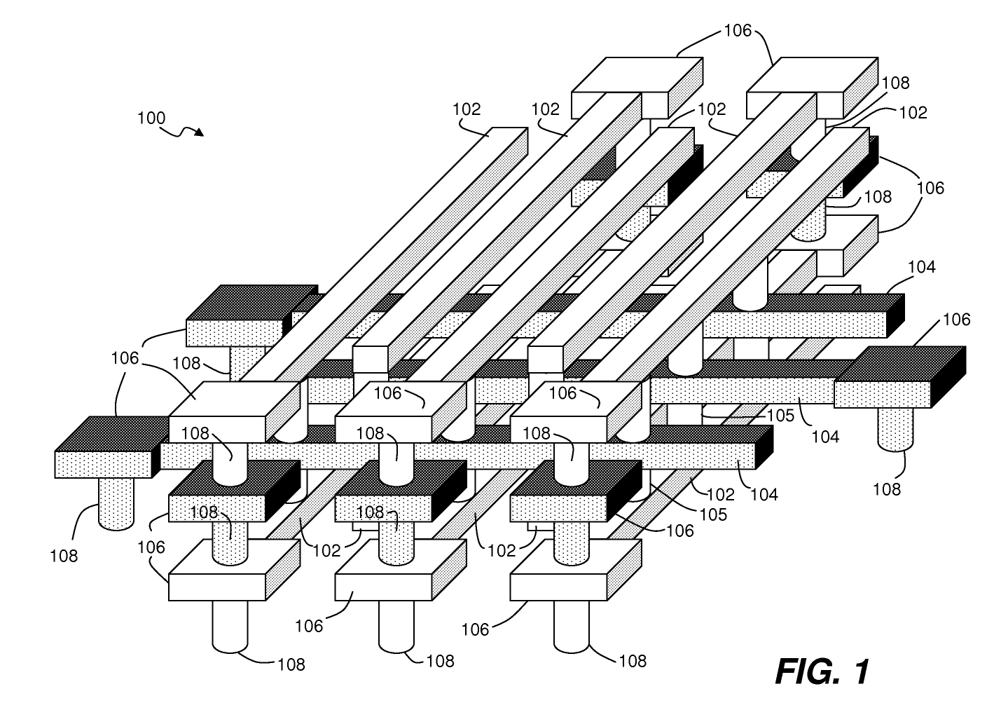

Turning to FIG. 1, a perspective view, structural representation 100 of interleaved word lines 102 and bit lines 104 of a simplified example three-dimensional partial memory array is depicted. The depicted interleaved memory lines 102, 104 and memory cell pillars 105 (disposed at the intersection of the memory lines 102, 104 (note that not all of the pillars are shown)), illustrate features formed by the methods and apparatus of the present invention. Details of the conventional aspects of forming three-dimensional memory arrays may be found in previously incorporated U.S. patent application Ser. No. 11/751,567. Thus, in some embodiments the multi-level memory array FIG. 1 includes memory cells pillars 105 that include a vertical diode and resistance changing layer in series at the crossing location of the word lines 102 and bit lines 104. An example of such a cross point diode memory array is described in more detail in above referenced U.S. Pat. No. 6,951,780.

In the present invention, each word line 102 (and each bit line 104) may include an enlarged contact pad region 106 at one end of the word line 102 (or bit line 104). Vias 108, extending down from each word line 102 and each bit line 104 are aligned to contact the enlarged contact pad region 106. Thus, the alignment of the vias 108 to the lower memory array lines 102, 104 is relaxed by interleaving. Interleaving enhances the advantage of imprint lithography by allowing use of a minimum pitch while enjoying a larger tolerance for via alignment. In such an embodiment, the line width and pitch may be scaled more than the via alignment variation. For example, 22 nm wide word lines 102 may be formed at a pitch of approximately 44 nm, however the effective line pitch at the via location maybe approximately 88 nm. In certain arrangements, alignment variation between layers may be as much as 22 nm. The methods of the present invention are scalable because the subtractive process allows formation of more robust memory lines 102, 104 and pillars 105 at a smaller feature size. Also, with regard to forming pillars 105, the aspect ratio of the pillars is not as challenging as with manufacturing prior art three dimensional memory arrangements because in the present invention, each memory line layer is associated with pillars 105.

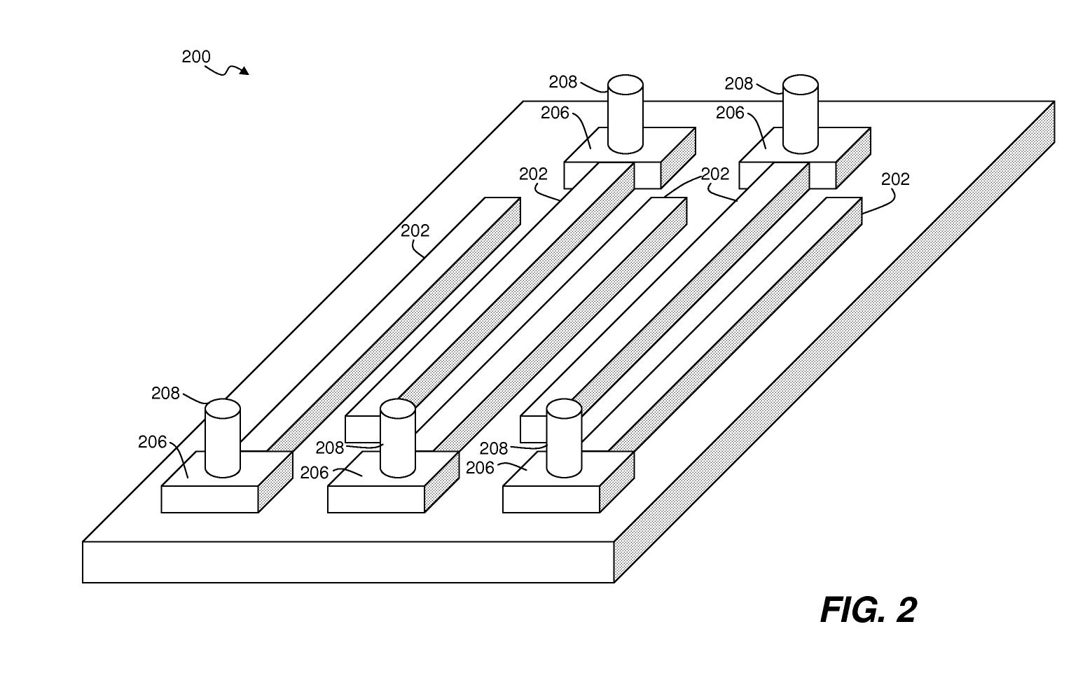

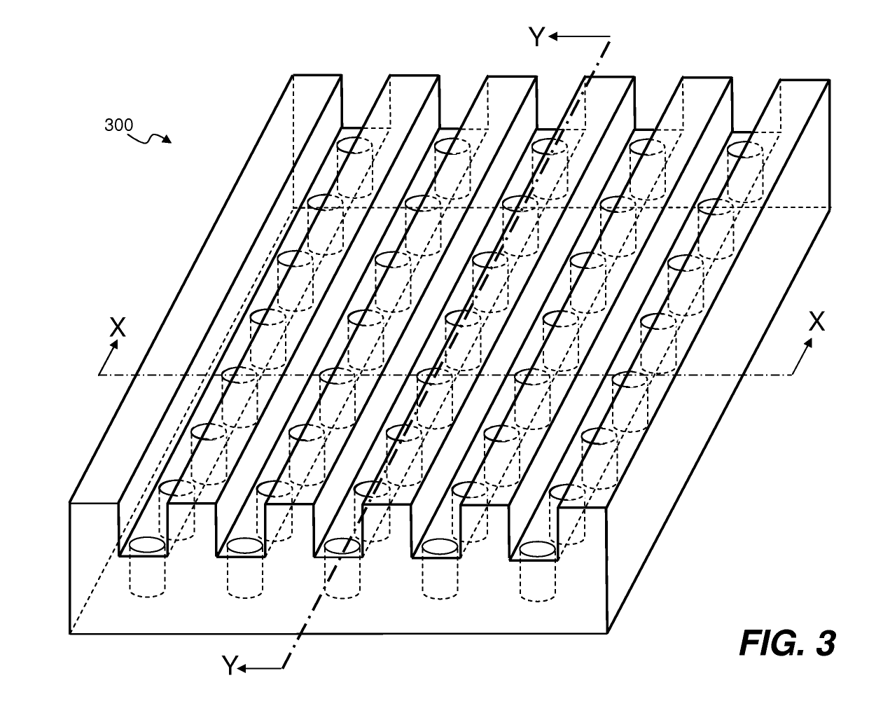

Turning to FIG. 2, an example of an imprint lithography mask 200 or template suitable for use in forming the memory lines 102, 104 and vias 108 of the three-dimensional memory array shown in FIG. 1 is depicted. Note that the depicted template 200 does not include features for forming memory pillars 105, however, in some embodiments, the template could include additional features for forming memory pillars 105. Also, note that a different template for forming memory pillars is described below with respect to FIG. 3. In either case, the imprint lithography mask 200 is formed by etching a desired pattern into a translucent blank made from, for example, quartz or fused silica. As shown, the imprint mask 200 includes interleaved rails 202 (corresponding to trenches) with wider landings 206 for forming contact pads at alternating ends of the rails 202. Pillars 208 (corresponding to vias) project upwards from the top surface of each of the landings 206. The imprint lithography mask 200 may be formed at the minimum dimensions (e.g., line width and pitch) achievable by whichever technology (e.g., 32 nm, 16 nm, 9 nm photolithography, immersion lithography, etc.) may be used to pattern the mask 200. Because a single mask 200 may be used repeatedly to form many layers of interconnect structures, the cost of manufacturing the mask 200 may be spread over each use of the mask 200. Thus, a net manufacturing cost reduction may be achieved by the methods and apparatus of the present invention.

In operation, the imprint lithography mask 200 is inverted from the orientation shown and used to imprint its complement shape into a liquid transfer layer. The liquid transfer layer is then hardened or cured by exposure to light (e.g., ultraviolet) or other radiation transmitted directly through the translucent imprint lithography mask 200. As will be described in more detail below, the hardened or cured transfer layer may be used during oxide etch to transfer the features of the imprint lithography mask 200 into a dielectric (e.g., oxide) layer.

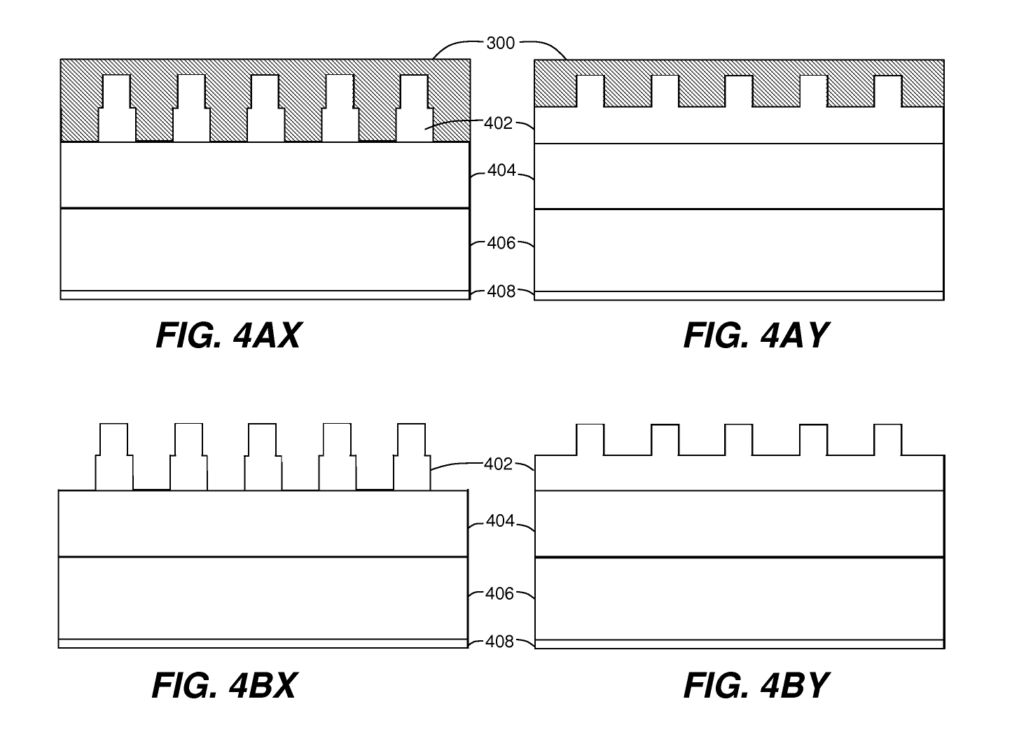

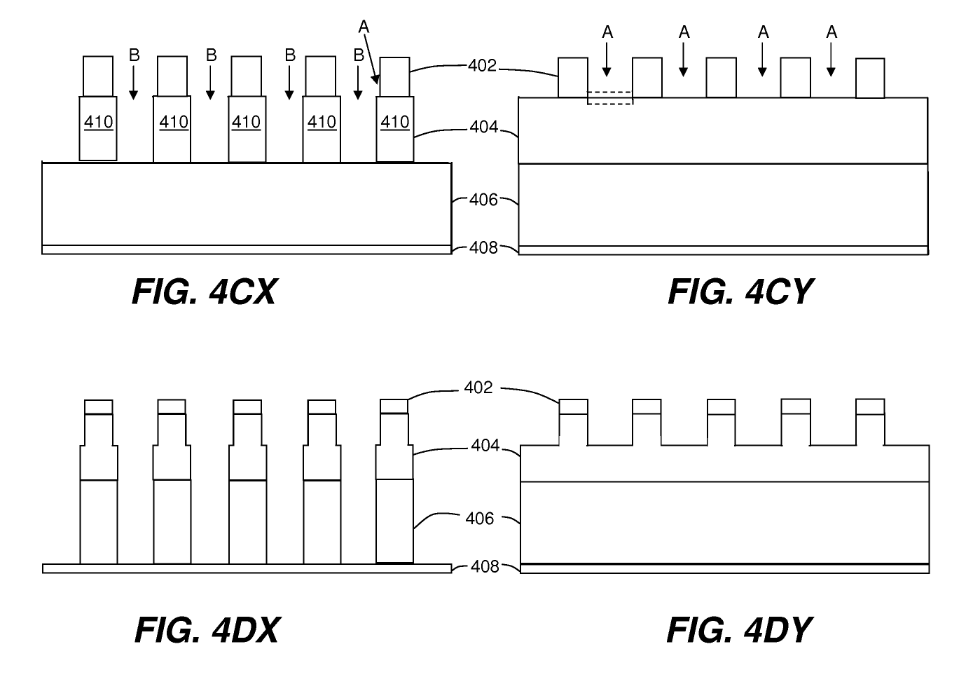

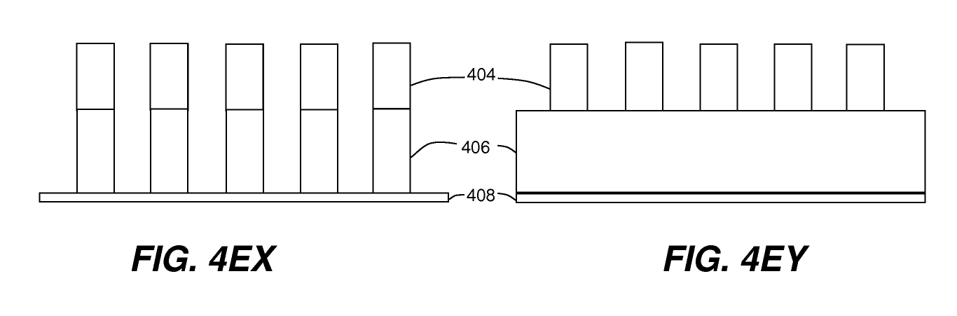

Turning to FIG. 3, a second example of an imprint lithography mask 300 or template suitable for forming memory lines 102, 104 and memory cell pillars 105 of a three-dimensional memory array is depicted. The example mask 300 corresponds to the mask 300 used in the processing sequence described below with respect to FIGS. 4AX through 4EX and 4AY through 4EY. As indicated by the X-X cross-sectional cut line and view arrows in FIG. 3, FIGS. 4AX, 4BX, 4CX, 4DX, and 4EX are cross-sectional views of a sequence of processing steps illustrating the formation of rails and pillars in a dielectric layer for use in manufacturing a memory array. As indicated in FIG. 3, the perspective of the “X” sequence of views is looking down the length of the trenches of the imprint lithography mask 300.

Further, as indicated by the Y-Y cross-sectional cut line and view arrows in FIG. 3, FIGS. 4AY, 4BY, 4CY, 4DY, and 4EY are also cross-sectional views of the sequence of processing steps illustrating the formation of rails and pillars in the dielectric layer. However, as also indicated in FIG. 3, the perspective of these views is looking across a trench and multiple holes of the imprint lithography mask 300. As with the imprint lithography mask 200 described above, the second example of an imprint lithography mask 300 or template may be formed by etching a desired pattern into a translucent blank made from, for example, quartz or fused silica. Further, the imprint lithography mask 300 may also be formed at the minimum dimensions (e.g., line width and pitch) achievable by whichever technology (e.g., 32 nm, 16 nm, 9 nm photolithography, immersion lithography, etc.) may be used to pattern the mask 300. As stated above, because a single mask 300 may be used repeatedly to form many layers of memory cell structures, the cost of manufacturing the mask 300 may be spread over each use of the mask 300. Thus, a net manufacturing cost reduction may be achieved by the methods and apparatus of the present invention.

Turning to FIGS. 4AX through 4EX and 4AY through 4EY, a first method of forming memory lines and pillars for a layer of a three-dimensional memory array is depicted from a front and side plan cross-sectional view, respectively. Note that, as indicated above, each side by side pair of drawings represents a cross-sectional plan view of the same process step where the drawing numbers ending in X correspond to views at the X-X cross-sectional cut line of FIG. 3 and the drawing numbers ending in Y correspond to views at the Y-Y cross-sectional cut line of FIG. 3, respectively. In the step depicted in FIGS. 4AX and 4AY, the inventive process of the present intention may begin with an initial arrangement of various material layers 402-408 selected to be suitable to form the desired devices in a memory array or other circuit.

Still looking at FIGS. 4AX and 4AY, the imprint lithography mask 300 is shown inserted in a transfer layer 402. Under the transfer layer 402, a memory cell layer 404 (e.g., a layer of polysilicon) has been deposited on a conductor or wire layer 406 (e.g., tungsten) which may be on a substrate 408. The transfer layer 402 facilitates concurrently transferring both the memory lines pattern and the pillars pattern from the imprint lithography mask 300 to the memory cell layer 404 and the wire layer 406.

In some embodiments, transfer layer 402 may be a photopolymerizable liquid material that is spin coated or otherwise deposited onto memory cell layer 404. The transfer layer 402, once cured, preferably provides high etch rate selectivity when subjected to subsequent etch processes that facilitate transfer of the desired pattern. In some embodiments, the transfer layer 402, may be resist or a conventional photoresist such as, for example, a spun on polymer PMMA and/or photo-curable materials such as those sold by Molecular Imprints, Inc. under the name S-FIL Monomat Ac01, which may be cured by exposure to I-line radiation (e.g., 365 nanometers) utilizing a photo source such as 100 Watt Hg—Se ultraviolet arc lamp. Another example of a photo-curable material that may be utilized is a material that includes ethylene glycol diacrylate (3-acryloxypropyl)tris(trimethylsiloxy)silane, t-butyl acrylate, and 2-hydroxy-2-methyl-1-phenyl-propan-1-one. Other practicable materials may be used. In some embodiments, the transfer layer 402 may have an initial thickness in the range of approximately 500 angstroms to approximately 5,000 angstroms.

The memory cell layer 404 is the layer in which the pillar structure shapes are to be ultimately formed. Memory cell layer 404 may include conductive or semiconducting material such as polysilicon. It may include any number of sub-layers of various different materials practicable for forming memory cells. For example, memory cell layer 404 may include a stack of layers comprising a lower barrier and adhesion layer, a semiconductor diode layer, an upper barrier and adhesion layer, a lower electrode layer, a switching metal oxide layer, a buffer oxide layer, and an upper electrode layer. For example the stack may comprise respectively a TiN layer, a deposited and recrystallized silicon layer with n type and p type doped regions to form a p-i-n diode, a TiN layer, an N+ silicon electrode layer, a hafnium oxide switching layer, a titanium Oxide buffer layer, and a titanium nitride upper electrode layer. Other barrier and adhesion layers may be tungsten nitride, tantalum nitride, or other stable conductive compounds. The switching layer material may comprise any transition metal oxide, or CMO layer, or amorphous carbon layer, or carbon nanotube layer, or conductive oxide layer, or phase change material or any other resistive switching material. The buffer layer may comprise a titanium layer that is subsequently annealed to form a sub-oxide of titanium, or a variable height tunnel barrier, or a tunnel oxide barrier, or a Silicon dioxide layer, or any material that reacts with the switching layer to change the oxygen content of the switching layer. In other embodiments memory cell layer 404 comprises the material layer stack of any passive element memory cell.

Below the memory cell layer 404, the conductive metal or wire layer 406 may include tungsten (W) or any practicable conductor. In some embodiments, the wire layer 406 may have a thickness in the range of approximately 200 angstroms to approximately 2000 angstroms. The wire layer 406 may be formed on a substrate 408 and/or may be part of another memory level (not shown).

During manufacturing, the imprint lithography mask 300 is depressed into transfer layer 402. Once the mask 300 is in position, the transfer layer 402 is then hardened by exposure to light (e.g., ultraviolet) or other radiation (e.g., an electron beam) transmitted directly through the translucent imprint lithography mask 300. As shown in FIGS. 4BX and 4BY, the mask 300 is removed after the transfer layer 402 has been cured and a complementary version of the features of the mask 300 remains. Next, an etch process is applied to form the structure depicted in FIGS. 4CX and 4CY. The memory cell layer 404 is etched in this step to transfer the rail shapes from the template layer 402 to the memory cell layer 404. The etch step in some embodiments is highly anisotropic to form high aspect ratio etched trenches with very straight side walls. In some embodiments, this etch step may be controlled by an etch end point determination from the etching tooling gasses at the time when the etch reaches the wire layer 406 in the regions B in FIG. 4CX. This etch forms effective mask shapes 410 in the memory cell layer 404 for forming wire layer 406 rails in a subsequent etch step. During the memory cell layer 404 etch there is erosion of the template layer 402 which transfers the pillar shapes from the top portion of the template layer to lower portions of the template layer as shown in FIGS. 4CX and 4CY. In some embodiments, the thicknesses of the template layer 402, depressions in imprint mask 300, and etch chemistries are chosen so the regions between pillar shapes A in FIG. 4CX and FIG. 3CY are etched to the interface between the template layer 402 and the memory cell layer 404 by the end of this etch step. However, optionally in some embodiments, region A may be etched to a level somewhat above or below (as shown by dotted lines within A in FIG. 4CY) the interface by the end of this etch step. Subsequent steps may be used to ensure the proper depth of the pillar shapes.

To form the structure depicted in FIGS. 4DX and 4DY, the exposed area of memory cell layer 404 between the pillars shown in FIGS. 4CX and 4CY is etched away and the consequently exposed wire layer 406 is anisotropically etched to form the final wire layer rails. In some embodiments, the wire layer etch is controlled by an etch end point detection from the etching tool when the wire layer material is removed from the trenches. In most cases, the template layer and memory cell layer erode during the wire layer etch. In some embodiments, (as shown in FIG. 4DY) at least some of the template layer 402 remains on top of the pillar shapes and at least some of the memory layer 404 remains between the pillar shapes at the end of the wire layer etch.

The final structure depicted in FIGS. 4EX and 4EY is formed by etching away the remaining memory cell layer 404 material remaining between the pillars by anisotropic dry etch techniques that may be controlled by an etch stop signal and then removing remaining template layer material from the top of the pillar shapes via a wet etch or cleaning processes. During these steps etching of the substrate layer 408 or etching of lower memory layers may be minimized by choice of etch and cleaning chemistries. Note that the exposed regions of substrate layer 408 (or a lower memory layer) may be a material such as silicon dioxide. In some embodiments, pillars forming lower memory layers may be partially eroded during this memory cell layer etch. This leaves a possibly smaller but still functional memory cell.

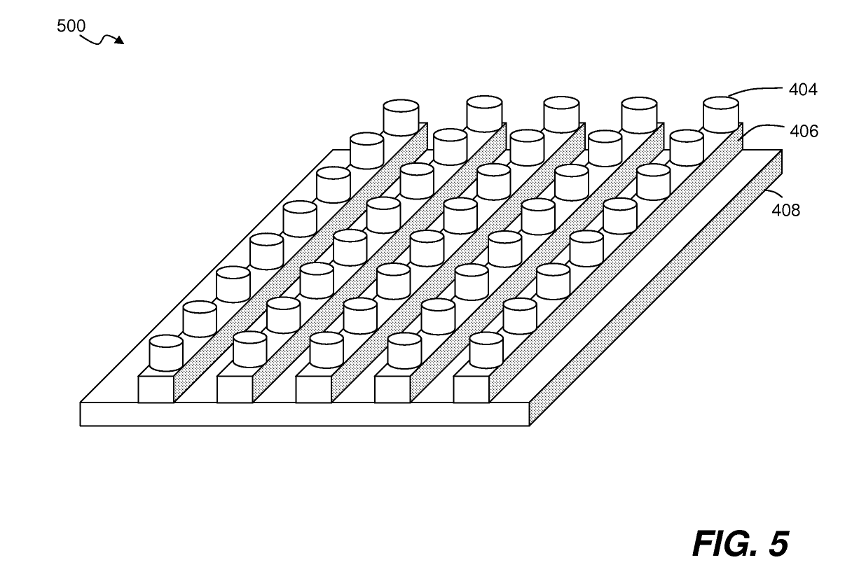

Turning to FIG. 5, a perspective view of a three dimensional memory layer 500 formed according to the process illustrated in FIGS. 4AX through 4EX and 4AY through 4EY is shown. Note that additional materials may be added to the layer 500. These may include an insulating layer which is deposited to fill the gaps between the three dimensional memory layer 500 and chemical-mechanical polished to form a flat surface. Additional memory layers (not shown, but see FIG. 1) may be formed on the layer 500 shown. In some embodiments, the memory layer 500 and/or additional layers may not include substrate 408. Also note that additional layers formed on the depicted layer 500 may be rotated (e.g., ˜90 degrees) relative to the depicted layer 500.

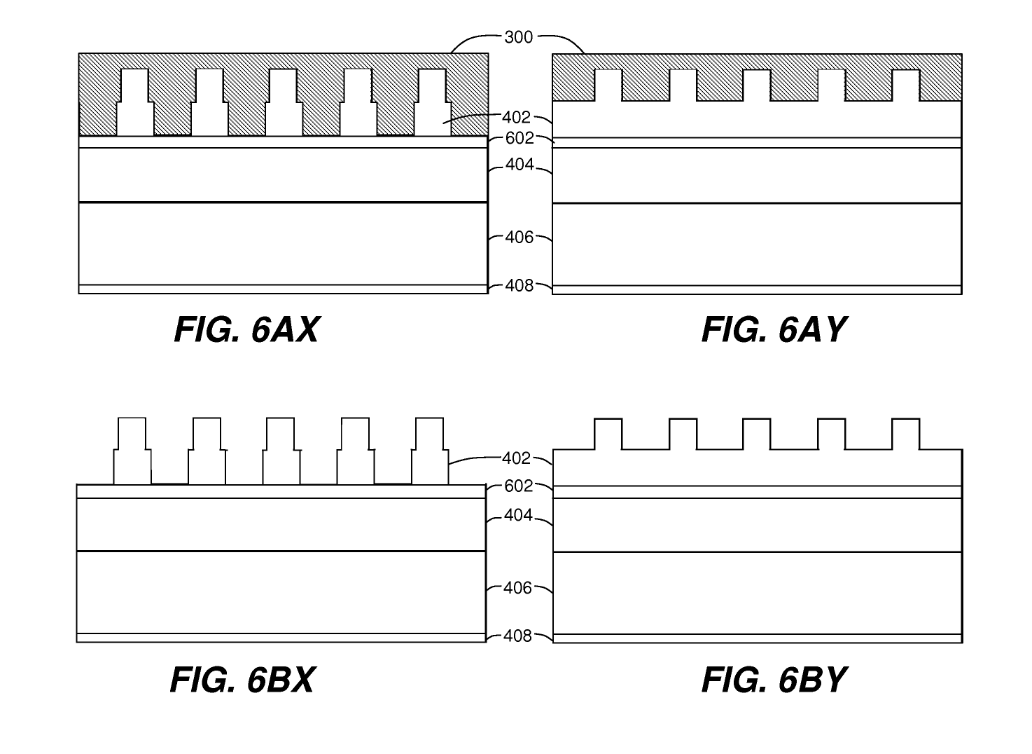

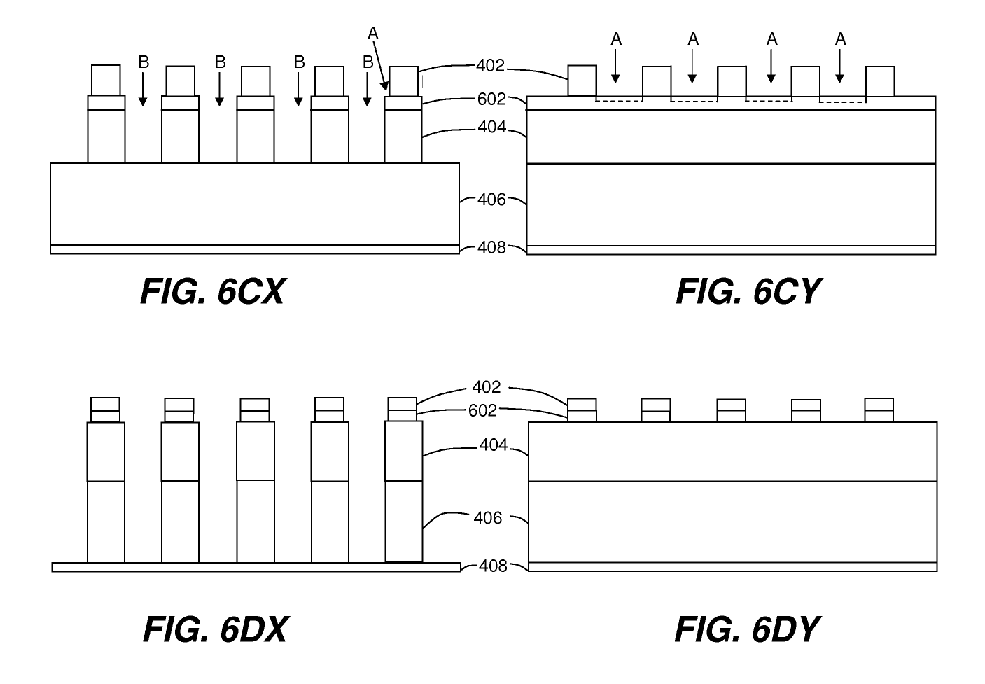

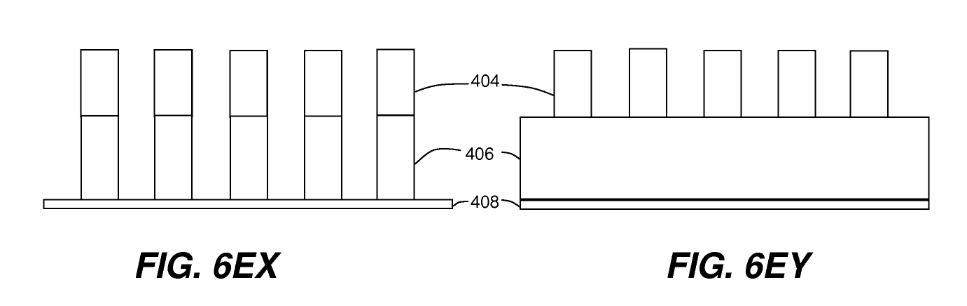

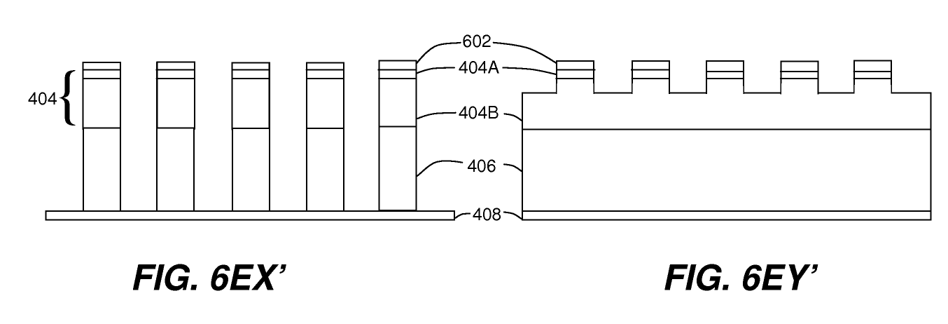

Turning now to FIGS. 6AX through 6EX and 6AY through 6EY, a second sequence of cross-sectional views (from a front (X) and a side (Y) perspective, respectively) representing a second example method of forming a layer of memory lines and pillars is shown. Note that, as indicated above, each side by side pair of drawings represents a cross-sectional plan view of the same process step where the drawing numbers ending in X correspond to views at the X-X cross-sectional cut line of FIG. 3 and the drawing numbers ending in Y correspond to views at the Y-Y cross-sectional cut line of FIG. 3, respectively.

In the step depicted in FIGS. 6AX and 6AY, the inventive process of the present intention may begin with an initial arrangement of various material layers 402, 602, 404, 406, and 408 selected to be suitable to form the desired devices in a memory array or other circuit. This second embodiment depicted in FIGS. 6AX through 6EX and 6AY through 6EY is similar to the first embodiment depicted in 4AX through 4EX and 4AY through 4EY except for a hardmask material layer 602 included between the transfer layer 402 and the memory cell layer 404. The hardmask material layer 602 may deposited on the memory cell layer 404 before the transfer layer 402 is deposited. In this alternative method, both the hard mask material layer 602 and the transfer layer 402 are used to transfer the dual topography of the imprint lithography mask 300 to the lower layers 404, 406.

As indicated above, between the transfer layer 402 and the memory cell layer 404, a layer of hardmask material 602 may be deposited. In some embodiments, a polycrystalline semiconductor material may be used as a hardmask 602 such as polysilicon, a polycrystalline silicon-germanium alloy, polygermanium or any other suitable material. In other embodiments, a material such as tungsten (W) or amorphous carbon (C) may be used. The hardmask material layer 602 thickness may be of varying thickness, depending on the etch process parameters used. In some embodiments, the hardmask material layer 602 may have an initial thickness in the range of approximately 500 angstroms to approximately 3000 angstroms.

The inclusion of the hardmask material layer 602 allows a more controlled etch of the transfer layer 402. The inclusion of the hard mask 602 also allows for a wider choice of etch gasses and etch time control for the trench etch regions while protecting the pillar regions as will be explained in more detail with reference to FIGS. 6CY and 6DY below.

Still looking at FIGS. 6AX and 6AY, the imprint lithography mask 300 is shown inserted in a transfer layer 402. Under the transfer layer 402, a hardmask material layer 602 and a memory cell layer 404 (e.g., a layer of polysilicon) has been deposited on a conductor or wire layer 406 (e.g., tungsten) which may be on a substrate 408. The transfer layer 402 and the hardmask material layer 602 facilitate concurrently transferring both the memory lines pattern and the pillars pattern from the imprint lithography mask 300 to the memory cell layer 404 and the wire layer 406. As indicated above, in some embodiments, transfer layer 402 may be a photopolymerizable liquid material that is spin coated or otherwise deposited onto hardmask material layer 602. The transfer layer 402, once cured, preferably provides high etch rate selectivity when subjected to subsequent etch processes that facilitate transfer of the desired pattern. In some embodiments, the transfer layer 402, may be resist or a conventional photoresist such as, for example, a spun on polymer PMMA and/or photo-curable materials such as those sold by Molecular Imprints, Inc. under the name S-FIL Monomat Ac01, which may be cured by exposure to I-line radiation (e.g., 365 nanometers) utilizing a photo source such as 100 Watt Hg—Se ultraviolet arc lamp. Another example of a photo-curable material that may be utilized is a material that includes ethylene glycol diacrylate (3-acryloxypropyl)tris(trimethylsiloxy)silane, t-butyl acrylate, and 2-hydroxy-2-methyl-1-phenyl-propan-1-one. Other practicable materials may be used. In some embodiments, the transfer layer 402 may have an initial thickness in the range of approximately 500 angstroms to approximately 5,000 angstroms.

The memory cell layer 404 is the layer in which the pillar structure shapes are to be ultimately formed. Memory cell layer 404 may include conductive or semiconducting material such as polysilicon. It may include any number of sub-layers of various different materials practicable for forming memory cells. For example, memory cell layer 404 may include a stack of layers comprising a lower barrier and adhesion layer, a semiconductor diode layer, an upper barrier and adhesion layer, a lower electrode layer, a switching metal oxide layer, a buffer oxide layer, and an upper electrode layer. For example the stack may comprise respectively a TiN layer, a deposited and recrystallized silicon layer with n type and p type doped regions to form a p-i-n diode, a TiN layer, an N+ silicon electrode layer, a hafnium oxide switching layer, a titanium Oxide buffer layer, and a titanium nitride upper electrode layer. Other barrier and adhesion layers may be tungsten nitride, tantalum nitride, or other stable conductive compounds. The switching layer material may comprise any transition metal oxide, or CMO layer, or amorphous carbon layer, or carbon nanotube layer, or conductive oxide layer, or phase change material or any other resistive switching material. The buffer layer may comprise a titanium layer that is subsequently annealed to form a sub-oxide of titanium, or a variable height tunnel barrier, or a tunnel oxide barrier, or a Silicon dioxide layer, or any material that reacts with the switching layer to change the oxygen content of the switching layer. In other embodiments memory cell layer 404 comprises the material layer stack of any passive element memory cell.

Below the memory cell layer 404, the conductive metal or wire layer 406 may include tungsten (W) or any practicable conductor. In some embodiments, the wire layer 406 may have a thickness in the range of approximately 200 angstroms to approximately 2000 angstroms. The wire layer 408 may be formed on a substrate 408 and/or may be part of another memory level (not shown).

During manufacturing, the imprint lithography mask 300 is depressed into transfer layer 402. Once the mask 300 is in position, the transfer layer 402 is then hardened by exposure to light (e.g., ultraviolet) or other radiation (e.g., an electron beam) transmitted directly through the translucent imprint lithography mask 300. As shown in FIGS. 6BX and 6BY, the mask 300 is removed after the transfer layer 402 has been cured and a complementary version of the features of the mask 300 remains. Next, an etch process is applied to form the structure depicted in FIGS. 6CX and 6CY. The memory cell layer 404 is etched in this step to transfer the rail shapes from the template layer 402 to the memory cell layer 404. The etch step in some embodiments is highly anisotropic to form high aspect ratio etched trenches with very straight, vertical side walls. In some embodiments, this etch step is controlled by an etch end point determination from the etching tooling gasses at the time when the etch reaches the wire layer 406 in the regions B in FIG. 6CX. This etch forms effective mask shapes 410 in the memory cell layer 404 for forming wire layer 406 rails in a subsequent etch step. During the memory cell layer 404 etch there is erosion of the template layer 402 which transfers the pillar shapes from the top portion of the template layer to lower portions of the template layer as shown in FIGS. 6CX and 6CY. In some embodiments, the thicknesses of the template layer 402, depressions in imprint mask 300, and etch chemistries are chosen so the regions between pillar shapes A in FIG. 6CX and FIG. 6CY are etched to the top of the hard mask layer 602 by the end of this etch step. An etch with high selectivity between the memory layer etching and hard mask etching may be used to enhance the etching. Some erosion of the hard mask layer 602 as shown by the dotted lines in FIG. 6CY at locations A is acceptable. The hard mask provides protection for the memory cell layer 404 at location A and therefore flexibility in choosing the etch chemistries and etch times. The pillar etch is determined in a later step and not determined by the thickness of the template layer in this step.

To form the structure depicted in FIGS. 6DX and 6DY, the etched memory layer 404 effectively acts as a mask for anisotropic etching of the trenches in the wire layer 406 as shown in FIG. 6DX. The hard mask material layer 602 erodes during the etch. In some embodiments the thickness of the hard mask layer may be sufficient to protect the memory layer in regions such as A during the etch. In some embodiments little or no hard mask thickness remains between the pillar shapes after the etch. To form the structure depicted in FIGS. 6EX and 6EY, any residue of hard mask layer in regions such as A in FIG. 6DY are removed and the memory layer is etched anisotropically to form pillars. In some embodiments there may be no template layer 402 remaining on the top of the pillar. An etch chemistry may be chosen to minimize etching of substrate layer 408 (or lower memory layers) between the memory lines during the pillar etch. Finally, any remaining transfer layer material 402 in FIGS. 6DX and 6DY and hardmask layer material 602 in FIGS. 6DX and 6Dy remaining on the tops of the pillars may be removed by wet etching or asking and cleaning steps. Additional oxide fill and chemical-mechanical polishing steps may be applied to insulate the memory cells.

Turning now to FIGS. 6EX′ and 6EY′, a third embodiment of the present invention is shown. This embodiment shares the sequence of steps depicted in FIGS. 6AX through 6DX and 6AY through 6DY with the second embodiment described above. However, instead of etching away all the memory cell layer 404 material remaining between the pillars show in FIG. 6DY, at regions such as A, a portion of the semiconductor diode material in the memory layer 404 is left in place. Since only a portion of the diode remains, there is still sufficient isolation between memory cells.

This alternative embodiment and structure may be desirable when the thickness of the wire layer 406 is relatively small and the thickness of the memory cell layer including the semiconductor stack is relatively large and a relatively thick transfer material layer 402 is used (or a combination of thick transfer material layer 402 and hardmask layer 602 are used) which may not be sufficient to mask the entire pillar etch. In this example embodiment, the memory layer 404 includes a memory region 404A on top of semiconductor material 404B doped into P-I-N regions to form a diode below the memory region. The material between the pillars is etched through the memory region 404A and the top p+ region and approximately half of the intrinsic (i) region. In other embodiments, more or less of the material between the pillars may be etched. The resulting structure gives sufficient electrical isolation from adjacent pillars. In some embodiments, a relatively thick memory cell layer 404 may be in the range of approximately 100 nm to approximately 300 nm including a semiconductor layer 404B in the range of approximately 50 nm to approximately 200 nm and the wire layer 406 may be in the range of 10 nm to approximately 50 nm. In some embodiments, a relatively thick transfer material layer 402 maybe from approximately 150 nm to approximately 500 nm. In some embodiments, a relatively thick combination of a transfer material layer 402 and hardmask layer 602 may be in the range of approximately 100 nm to approximately 500 nm.

During programming, a pulsing programming method may be employed to avoid disturbing or otherwise affecting adjacent pillars. Pulsing or pulsed programming methods are known in the art and details of such methods may be found for example in U.S. Pat. Nos. 6,822,903 and 6,963,504 (Attorney Docket No. MXA-0098) entitled “Apparatus And Method For Disturb-Free Programming Of Passive Element Memory Cells” which is hereby incorporated herein by reference. Pulsed programming may be used with any layer stack for which such programming is practicable and particularly with layer stacks that require high programming voltages. In such embodiments, pulsed programming of the memory cells reduces the chance that programming one cell will disturb or alter an adjacent cell.

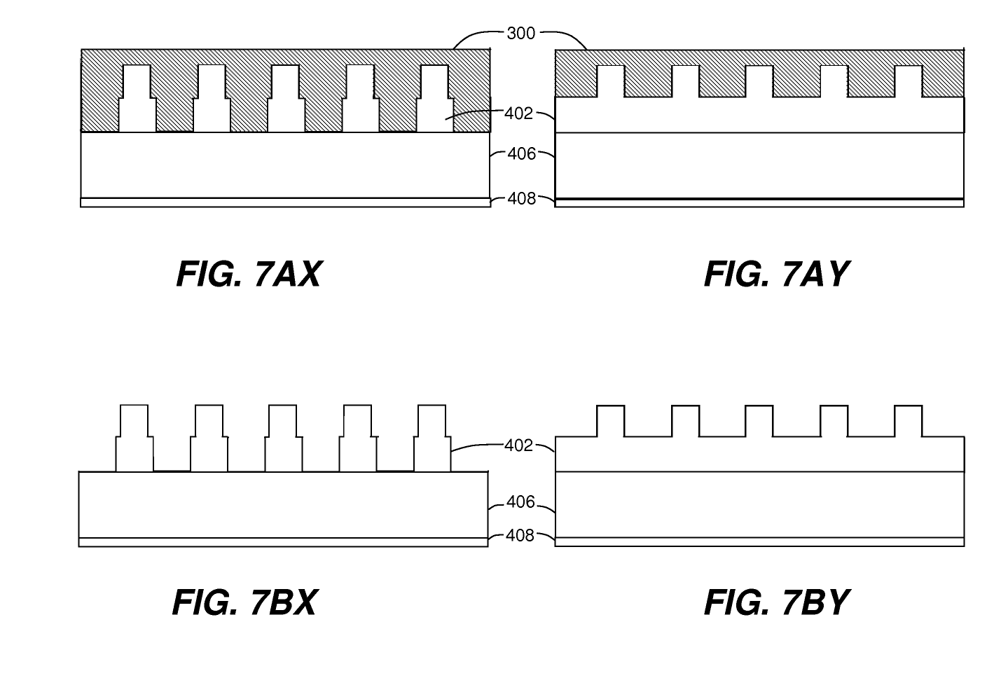

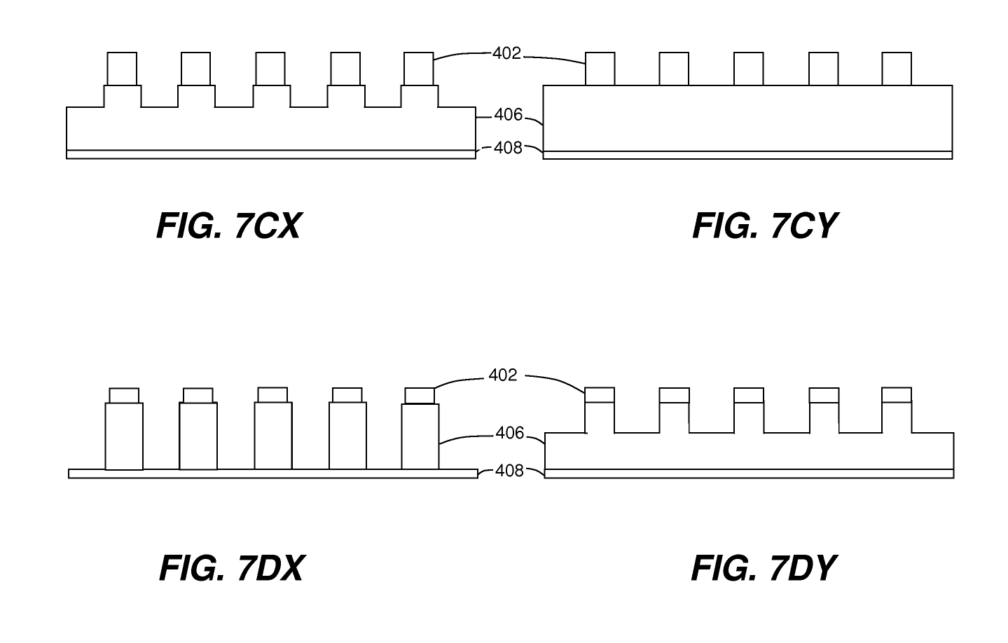

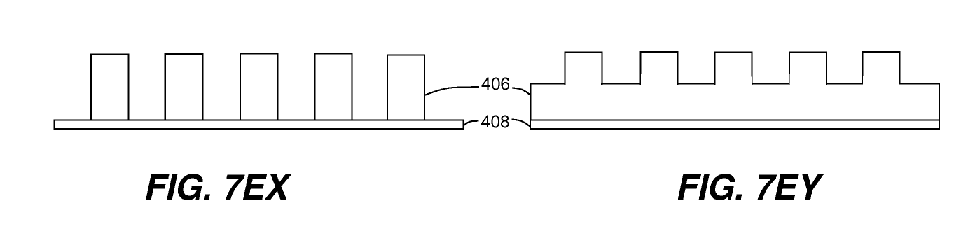

Turning now to FIGS. 7AX through 7EX and 7AY through 7EY, a fourth sequence of cross-sectional views (from a front (X) and a side (Y) perspective, respectively) representing a fourth example method is shown. This method involves forming a layer of memory lines and conductive vias on top of the lines. Note that, as indicated above, each side by side pair of drawings represents a cross-sectional plan view of the same process step where the drawing numbers ending in X correspond to views at the X-X cross-sectional cut line of FIG. 3 and the drawing numbers ending in Y correspond to views at the Y-Y cross-sectional cut line of FIG. 3, respectively.

In the step depicted in FIGS. 7AX and 7AY, the inventive process of the present intention may begin with an initial arrangement of various material layers 402, 406, and 408 selected to be suitable to form desired structures for a memory array or other circuit. Conductive lines and conductive vias (e.g., vertical connections to other memory layers) on top of the lines are formed of the same material using an imprint lithography mask 300 with at least two features of different depths, where the height difference in the imprint lithography mask 300 is transferred to transfer layer 402 in the step depicted in FIGS. 7AX and 7AY.

Still looking at FIGS. 7AX and 7AY, the imprint lithography mask 300 is shown inserted in a transfer layer 402. Under the transfer layer 402, a conductive or wire layer 406 (e.g., tungsten) is formed. As shown, the conductive layer 406 may be formed on a substrate 408. The transfer layer 402 facilitates concurrently transferring both the conductive lines pattern and the conductive vias pattern from the imprint lithography mask 300 to the conductive layer 406. In some embodiments, transfer layer 402 may be a photopolymerizable liquid material that is spin coated or otherwise deposited onto conductive layer 406. The transfer layer 402, once cured, preferably provides high etch rate selectivity when subjected to subsequent etch processes that facilitate transfer of the desired pattern.

In some embodiments, the transfer layer 402, may be resist or a conventional photoresist such as, for example, a spun on polymer PMMA and/or photo-curable materials such as those sold by Molecular Imprints, Inc. under the name S-FIL Monomat Ac01, which may be cured by exposure to I-line radiation (e.g., 365 nanometers) utilizing a photo source such as 100 Watt Hg—Se ultraviolet arc lamp. Another example of a photo-curable material that may be utilized is a material that includes ethylene glycol diacrylate (3-acryloxypropyl)tris(trimethylsiloxy)silane, t-butyl acrylate, and 2-hydroxy-2-methyl-1-phenyl-propan-1-one. Other practicable materials may be used. In some embodiments, the transfer layer 402 may have an initial thickness in the range of approximately 500 angstroms to approximately 5,000 angstroms.

In this embodiment of the present invention, the conductive layer 406 is the layer in which both the conductive lines and conductive via shapes is to be ultimately formed. Note that although a particular number of spaced conductive vias are shown in the drawings as an example, a mask 300 with any desired number of conductive vias may be used with any desired spacing. For example, conductive lines with only a single conductive via at alternating ends of the conductive lines may be formed. Below the transfer layer 402, the conductive metal or wire layer 406 may include tungsten (W) or any practicable conductor. In some embodiments, the conductive layer 406 may have a thickness in the range of approximately 1000 angstroms to approximately 5000 angstroms. The conductive layer 408 may be formed on a substrate 408 and/or may be part of or coupled to another memory level (not shown).

During manufacturing, the imprint lithography mask 300 is depressed into transfer layer 402. Once the mask 300 is in position, the transfer layer 402 is then hardened by exposure to light (e.g., ultraviolet) or other radiation (e.g., an electron beam) transmitted directly through the translucent imprint lithography mask 300. As shown in FIGS. 7BX and 7BY, the mask 300 is removed after the transfer layer 402 has been cured and a complementary version of the features of the mask 300 remains. Next, an etch process is applied to the transfer layer 402 to form the structure depicted in FIGS. 7CX and 7CY. The conductive layer 406 is anisotropically etched to form both conductive vias and lines. As the etch proceeds, the structure proceeds sequentially from looking like FIGS. 7CX and 7CY, to FIGS. 7DX and 7DY, and ultimately to FIGS. 7EX and 7EY where all of the transfer layer 402 has been removed. In some embodiments, the anisotropic etch may be terminated based on a etch endpoint signal when the conductive layer 406 is etch through to the bottom as shown in FIG. 7DX between the rails and any remaining transfer layer material 402 on the pillars is removed by wet etch or asking and cleaning. In some alternative embodiments, the etch conditions may be changed during various phases of the material etch step.

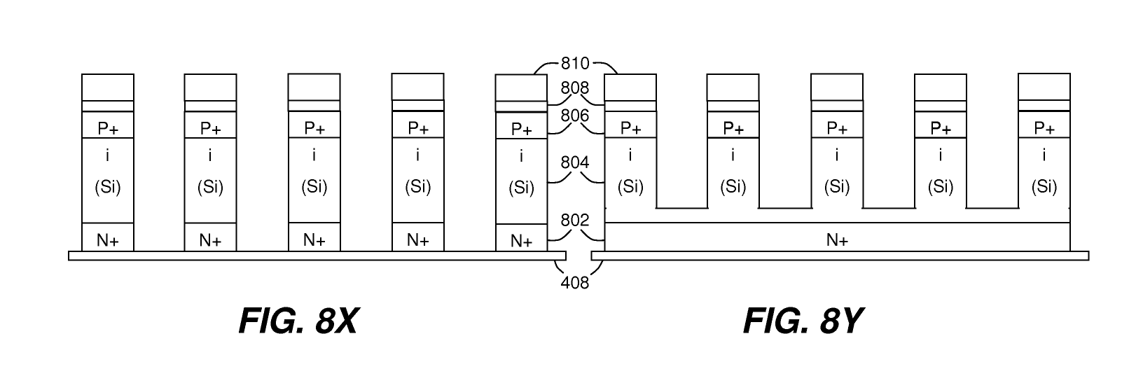

Turning now to FIGS. 8X and 8Y, a fifth embodiment of the present invention is represented by two perpendicular cross-sectional views. In some of the above-described embodiments, the pillar structures included memory material for forming memory cells. Further, the line or rail structures included only conductive material for forming wires. In the embodiment depicted in FIGS. 8X and 8Y (as with the embodiment of FIGS. 6EX′ and 6EY′), the rail structures include material that is part of the memory cells (e.g., semiconductor material for a diode) such that a portion of each memory cell is formed within the pillar structures and a portion is formed in the rail structures. For example, the material layers may be initially deposited which include a transfer material layer 810 on a memory material layer 808 which is on a relatively thick stack of semiconductor material layers 806, 804, 802. In some embodiments, a relatively thick combination of thick stack of semiconductor material layers 806, 804, 802 may be in the range of approximately 50 nm to approximately 200 nm.

The semiconductor material 806, 804, 802 may include an N-I-P doping structure suitable to form diodes. The layer stack may be formed on a substrate 408 or another memory layer (not shown). Using steps similar to those detailed above, the layer stack can be imprinted with a template 300 and then etched to form the structure depicted in FIGS. 8X and 8Y. Note that the etch into the semiconductor material is stopped (e.g., the etch is only partial) such that the memory material 808 will be in the pillar-shaped structure and the semiconductor material 806, 894, 802 will be partially in the pillar-shaped structure and partially in the shape of lines or rails.

An advantage of this method is that the aspect ratio (e.g., the ratio of height to width) of the semiconductor material etch is reduced. The pillar structures have enhanced adhesion and improved resistance to toppling over because they are relatively shorter and are formed with a continuous material connection to the line structure. In some embodiments, a conductive rail may be formed below the semiconductor material in a separate lithography step. As with the above described memory layers, the memory material 808 may be one time programmable (OTP), rewritable, or any suitable memory material for passive element cells including switchable metal oxides or carbon nanotube material. As with the above described methods, any remaining transfer material 810 (and/or hardmask material) may be removed with further processing beyond the step show in FIGS. 8X and 8Y.

As described above with respect to the third alternative embodiment, pulsed programming may be used with this embodiment to insure that programming of adjacent pillars do not affect each other.

In various embodiments of a three-dimensional memory array, different combinations of the depicted structures described above may be employed together. Any practicable combinations may be employed.

The foregoing description discloses only exemplary embodiments of the invention. Modifications of the above-disclosed embodiments of the present invention which fall within the scope of the invention will be readily apparent to those of ordinary skill in the art. For instance, although only imprint lithography masks with two imprint depths where depicted, in some embodiments, any practicable number of imprint depths may be employed.

Accordingly, while the present invention has been disclosed in connection with exemplary embodiments thereof, it should be understood that other embodiments may fall within the spirit and scope of the invention as defined by the following claims.

1. A method of forming a memory layer in a three-dimensional memory array, the method comprising:
forming a template having a plurality of depths, wherein at least one depth corresponds to a first memory line and wherein at least one depth corresponds to a memory cell pillar;
imprinting the template into a transfer material;
curing the transfer material; and
forming a memory layer using the imprinted and cured transfer material.

2. The method of claim 1 wherein forming the template includes forming the template from at least one of quartz and fused silica.

3. The method of claim 1 wherein forming the template includes forming a template including a plurality of trenches corresponding to rails for a plurality of memory lines.

4. The method of claim 1 wherein forming the template includes forming a template including a plurality of holes corresponding to pillars for a plurality of memory cells.

5. The method of claim 1 wherein forming the template includes forming a template including a plurality of holes corresponding to pillars for a plurality of memory cells and a plurality of trenches corresponding to rails for a plurality of memory lines.

6. The method of claim 5 wherein forming the template includes forming the holes in the trenches.

7. The method of claim 6 wherein forming the holes in the trenches includes forming holes adapted to be used to form a pillar structure in a transfer material.

8. The method of claim 7 wherein forming the holes in the trenches includes forming holes wherein a combined depth of the holes and trenches is greater than a depth of the trenches alone.

9. The method of claim 1 wherein imprinting the template into a transfer material includes imprinting the template into a transfer material that includes resist.

10. The method of claim 1 wherein imprinting the template into a transfer material includes imprinting the template to form a pattern of rails and pillars in the transfer material.

11. The method of claim 1 wherein imprinting the template into a transfer material includes imprinting the template into a transfer material layer formed on a hardmask layer which is formed on a memory material layer which is formed on a conductive material layer.

12. The method of claim 11 wherein imprinting the template into the transfer material layer includes imprinting the template into the transfer material layer such that at least one imprint depth reaches an area of the hardmask layer.

13. The method of claim 12 wherein forming a memory layer using the imprinted and cured transfer material includes etching the area of the hardmask layer reached by the template.

14. The method of claim 13 wherein forming a memory layer using the imprinted and cured transfer material includes etching the memory material layer area below the etched area of the conductive material layer.

15. The method of claim 14 wherein forming a memory layer using the imprinted and cured transfer material includes etching the conductive material layer area below the etched area of the memory material layer.

16. The method of claim 1 wherein imprinting the template into a transfer material includes imprinting the template into a transfer material layer formed on a memory material layer which is formed on a conductive material layer.

17. The method of claim 16 wherein imprinting the template into the transfer material layer includes imprinting the template into the transfer material layer such that at least one imprint depth reaches an area of the memory material layer.

18. The method of claim 17 wherein forming a memory layer using the imprinted and cured transfer material includes etching the area of memory material layer reached by the template.

19. The method of claim 18 wherein forming a memory layer using the imprinted and cured transfer material includes etching the conductive material layer area below the etched area of the memory material layer to form memory cell pillars on conductive lines.

20. A memory layer in a three-dimensional memory array, the memory layer comprising:
a plurality of memory lines and pillars formed by a process using an imprint lithography template having a plurality of depths, wherein at least one depth corresponds to the memory lines and wherein at least one depth corresponds to the pillars; and
a plurality of memory cells formed in the pillars and operatively coupled to the memory lines.

21. The memory layer of claim 20 wherein the imprint lithography template is formed from at least one of quartz and fused silica.

22. The memory layer of claim 21 wherein the template includes a plurality of trenches corresponding to rails for the plurality of memory lines.

23. The memory layer of claim 22 wherein the template includes a plurality of holes corresponding to pillars for the plurality of memory cells.

24. The memory layer of claim 21 wherein the template includes a plurality of holes corresponding to pillars for the plurality of memory cells and a plurality of trenches corresponding to rails for the plurality of memory lines.

25. The memory layer of claim 24 wherein the template includes the holes disposed within the trenches.

26. The memory layer of claim 25 wherein the template includes the holes disposed in the trenches along a length of the trenches.

27. The memory layer of claim 24 wherein the template includes the holes disposed within the trenches and having a depth greater than a depth of the trenches alone.

28. The memory layer of claim 24 wherein the template includes a plurality of landings corresponding to contact pads.

29. The memory layer of claim 21 wherein the template includes a plurality of holes corresponding to pillars for memory cells, a plurality of trenches corresponding to rails for memory lines, and a plurality of landings corresponding to contact pads.

30. The memory layer of claim 29 wherein the template includes a landing at alternate opposite ends of each adjacent trench.

31. The memory layer of claim 30 wherein the template includes features for forming vias disposed on the landings.

32. A memory layer formed using the method of claim 1.

33. An imprint lithography mask for manufacturing a memory layer in a three dimensional memory, the mask comprising:
a translucent material formed with features for making an imprint in a transfer material to be used in a double subtractive process, the mask having a plurality of imprint depths,
wherein at least one imprint depth corresponds to trenches for forming memory lines and wherein at least one depth corresponds to holes for forming pillar-shaped memory cells on the memory lines.

34. The imprint lithography mask of claim 33 wherein the imprint lithography mask is formed from at least one of quartz and fused silica.

35. The imprint lithography mask of claim 34 wherein the mask includes a plurality of trenches for forming corresponding rails for a plurality of memory lines.

36. The imprint lithography mask of claim 34 wherein the mask includes a plurality of holes for forming corresponding pillars for a plurality of memory cells.

37. The imprint lithography mask of claim 34 wherein the mask includes a plurality of holes corresponding to pillars for a plurality of memory cells and a plurality of trenches corresponding to rails for a plurality of memory lines.

38. The imprint lithography mask of claim 37 wherein the mask includes the holes disposed within the trenches.

39. The imprint lithography mask of claim 38 wherein the holes disposed within the trenches are disposed along a length of the trenches.

40. The imprint lithography mask of claim 39 wherein the holes disposed within the trenches have a depth greater than a depth of the trenches alone.

41. The imprint lithography mask of claim 40 wherein the mask includes a plurality of landings corresponding to contact pads.

42. The imprint lithography mask of claim 34 wherein the mask includes a plurality of holes corresponding to pillars for memory cells, a plurality of trenches corresponding to rails for memory lines, and a plurality of landings corresponding to contact pads.

43. The imprint lithography mask of claim 42 wherein the mask includes a landing at alternate opposite ends of each adjacent trench.

44. The imprint lithography mask of claim 33 wherein the mask is adapted to concurrently form memory lines and memory cells for a memory layer by imprinting the mask into a transfer material that includes resist.

45. The imprint lithography mask of claim 33 wherein the mask is adapted to be used to form a memory layer from a layer of transfer material deposited on a memory material layer which is deposited on a conductive layer.

46. The imprint lithography mask of claim 33 wherein the mask is adapted to be used to form a memory layer from a layer of transfer material deposited on a hardmask layer which is deposited on a memory layer which is deposited on a conductive layer.

46. A three dimensional memory array comprising:
a plurality of horizontal memory layers formed on top of each other and electrically coupled to each other by vertical zias, the zias formed from aligned vias in each memory layer, and the memory layers including a plurality of memory lines and the memory cell pillars, both formed concurrently using an imprint lithography mask.

47. The three dimensional memory array of claim 46 wherein the plurality of memory lines and pillars are formed by a double subtractive process using the imprint lithography mask having a plurality of depths, wherein at least one depth corresponds to the memory lines and wherein at least one depth corresponds to the pillars.

48. The three dimensional memory array of claim 47 wherein the imprint lithography mask is formed from at least one of quartz and fused silica.

49. The three dimensional memory array of claim 48 wherein the imprint lithography mask includes a plurality of trenches corresponding to rails for a plurality of memory lines.

50. The three dimensional memory array of claim 48 wherein the imprint lithography mask includes a plurality of holes corresponding to pillars for a plurality of memory cells.

51. The three dimensional memory array of claim 48 wherein the imprint lithography mask includes a plurality of holes corresponding to pillars for a plurality of memory cells and a plurality of trenches corresponding to rails for a plurality of memory lines.

52. The three dimensional memory array of claim 51 wherein the imprint lithography mask includes the holes disposed in the trenches.

53. The three dimensional memory array of claim 46 wherein the memory layers are formed by imprinting the imprint lithography mask into a transfer material that includes resist.

54. The three dimensional memory array of claim 53 wherein the memory layers are formed using a layer of transfer material deposited on a memory material layer which is deposited on a conductive layer.
